(19) United States
(12) Patent Application Publication
(10) Pub. No.: US 2025/0053718 A1
(43) Pub. Date: Feb. 13, 2025

(54) SYSTEMS AND METHODS TO MODEL AND MONITOR ENVIRONMENTAL IMPACT OF WELL COMPLETION ACTIVITIES

(71) Applicant: Schlumberger Technology Corporation, Sugar Land, TX (US)

(72) Inventors: Herbe Gomez Conzatti y Martinez, Sugar Land, TX (US); Karishma Mohini Prasad, Sugar Land, TX (US); Chad Kraemer, Houston, TX (US); Salvador Ayala, Houston, TX (US)

(21) Appl. No.: 18/723,707

(22) PCT Filed: Mar. 10, 2023
(86) PCT No.: PCT/US2023/014935

§ 371 Date: Jun. 24, 2024

Related U.S. Application Data
(60) Provisional application No. 63/269,129, filed on Mar. 10, 2022.

(51) Int. Cl. G06F 30/28

(52) U.S. Cl. CPC G06F 30/28

(57) ABSTRACT

Systems and methods presented herein generally relate to an environmental impact modeling and monitoring system that enables forecasting, real-time monitoring, predicting (e.g., via back-calculation using historical data, statistical data, and/or manual inputs relating to equipment specifications, and so forth), and measuring the environmental impact of well completion activities of an oil and gas production system. These activities include, but are not limited to, water management, sand management, fracturing operations, and all associated mobilization, among other activities. In certain embodiments, the outputs of the environmental impact modeling and monitoring system may be quantified parameters associated with sustainability metrics recognized across various industries.

### CROSS-REFERENCE TO RELATED APPLICATIONS

This application claims the benefit of U.S. Provisional Application No. 63/269,129 entitled “Systems and Methods to Model and Monitor Environmental Impact of Well Completion Activities,” filed Mar. 10, 2022, the disclosure of which is incorporated herein by reference in its entirety.

### BACKGROUND

The present disclosure generally relates to using field data collected in substantially real time during operation of an oil and gas production system to model and monitor environmental impact of well completions activities of the oil and gas production system.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as an admission of any kind.

Completion services are required for most oil and gas wells and include, but are not limited to, fracturing, perforating, completion staging, flowback, and so forth. Successful well completion processes require a multitude of resources, including equipment, proppants, water, diesel, and others. Completion processes also have environmental implications such as engine emissions while driving or pumping, fugitive methane emissions, dust and venting of produced substances into the atmosphere during the well start up process, and so forth. Services associated with completion processes, such as flowback water transfer, treatment, and disposal also have an environmental footprint. Some development impacts are more social in nature (e.g., traffic, noise, and so forth), but also need to be considered during completion planning. The full environmental profile of completion operations is so wide that challenges exist for an operator to fully assess and quantify it before and after performing the operations.

### SUMMARY

A summary of certain embodiments described herein is set forth below. It should be understood that these aspects are presented merely to provide the reader with a brief summary of these certain embodiments and that these aspects are not intended to limit the scope of this disclosure.

Certain embodiments of the present disclosure include a method that includes detecting, via one or more sensors of an oil and gas production system, operational data relating to one or more well completion activities of the oil and gas production system. The method also includes automatically calculating, via an environmental impact modeling and monitoring system, one or more sustainability impact metrics relating to the well completion activities of the oil and gas production system based at least in part on the operational data detected by the one or more sensors and/or one or more manual inputs relating to equipment specifications of equipment of the of the oil and gas production system.

Certain embodiments of the present disclosure also include a system that includes one or more sensors of an oil and gas production system, The one or more sensors are configured to detect operational data relating to one or more well completion activities of the oil and gas production system. The system also includes an environmental impact modeling and monitoring system configured to automatically calculate one or more sustainability impact metrics relating to the well completion activities of the oil and gas production system based at least in part on the operational data detected by the one or more sensors and/or one or more manual inputs relating to equipment specifications of equipment of the of the oil and gas production system.

Various refinements of the features noted above may be undertaken in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings, in which:

FIG. 1 illustrates a well site having a drilling rig positioned above a subterranean formation that includes one or more oil and/or gas reservoirs, in accordance with embodiments of the present disclosure;

FIG. 2 illustrates an example oil and gas production system, in accordance with embodiments of the present disclosure;

FIG. 3 is a schematic diagram of various sub-systems of the oil and gas production system of FIG. 2, in accordance with embodiments of the present disclosure;

FIG. 4 illustrates various equipment and infrastructure that may be mobilized and demobilized as part of mobilization and demobilization illustrated in FIG. 3, in accordance with embodiments of the present disclosure;

FIG. 5 illustrates various consumable materials that may be transported to the oil and gas production system as part of consumable materials transportation illustrated in FIG. 3, in accordance with embodiments of the present disclosure;

FIG. 6 illustrates example hydraulic fracturing operations illustrated in FIG. 3, in accordance with embodiments of the present disclosure;

FIG. 7 illustrates flowback/produced water transportation and flowback disposal and/or reuse illustrated in FIG. 3, in accordance with embodiments of the present disclosure;

FIG. 8 illustrates a system that includes an environmental impact modeling and monitoring system to monitor and control an oil and gas production system, in accordance with embodiments of the present disclosure;

FIG. 9 illustrates a process workflow that may be performed by an environmental impact modeling and monitoring system to model, monitor, and measure the environmental impact associated with well completion activities of an oil and gas production system in substantially real time, in accordance with embodiments of the present disclosure;

FIG. 10 illustrates a sensor that may detect data relating to well completion activities of an oil and gas production system in substantially real time, in accordance with embodiments of the present disclosure; and

FIG. 11 is a flow diagram of a method of use of an environmental impact modeling and monitoring system, in accordance with embodiments of the present disclosure.

### DETAILED DESCRIPTION

One or more specific embodiments of the present disclosure will be described below. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “connect,” “connection,” “connected,” “in connection with,” and “connecting” are used to mean “in direct connection with” or “in connection with via one or more elements”; and the term “set” is used to mean “one element” or “more than one element.” Further, the terms “couple,” “coupling,” “coupled,” “coupled together,” and “coupled with” are used to mean “directly coupled together” or “coupled together via one or more elements.”

In addition, as used herein, the terms “real time”, “real-time”, or “substantially real time” may be used interchangeably and are intended to describe operations (e.g., computing operations) that are performed without any human-perceivable interruption between operations. For example, as used herein, data relating to the systems described herein may be collected, transmitted, and/or used in control computations in “substantially real time” such that data readings, data transfers, and/or data processing steps occur once every second, once every 0.1 second, once every 0.01 second, or even more frequent, during operations of the systems (e.g., while the systems are operating). In addition, as used herein, the terms “continuous”, “continuously”, or “continually” are intended to describe operations that are performed without any significant interruption. For example, as used herein, control commands may be transmitted to certain equipment every five minutes, every minute, every 30 seconds, every 15 seconds, every 10 seconds, every 5 seconds, or even more often, such that operating parameters of the equipment may be adjusted without any significant interruption to the closed-loop control of the equipment. In addition, as used herein, the terms “automatic”, “automated”, “autonomous”, and so forth, are intended to describe operations that are performed are caused to be performed, for example, by a computing system (i.e., solely by the computing system, without human intervention).

As described in greater detail herein, several dynamic activities occur to fulfill completion activities for a well including water, chemical, and sand management activities, transportation of relevant consumables, the mobilization/demobilization of the equipment needed to deliver the various elements, and operation service delivery at the fracturing wellsite, among other things. There are currently no tools available to understand and estimate the sustainability impact of completion activities that use field data. In particular, there are currently no tools available in the realm of oilfield applications with the ability to assess footprints associated with oilfield operations that are critical to analyzing and adapting proposed workflows and to deliver on carbon-conscious commitments.

As described in greater detail herein, the embodiments described herein provide an environmental impact modeling and monitoring system that enables forecasting, real-time monitoring, and measuring the environmental impact of well completion activities of an oil and gas production system. These activities include, but are not limited to, water management, sand management, fracturing operations, and all associated mobilization, among other activities. In certain embodiments, the outputs of the environmental impact modeling and monitoring system may be quantified parameters associated with sustainability metrics recognized across various industries. In particular, the environmental impact modeling and monitoring system enables operators to forecast the environmental impact based on job parameters inputted into the environmental impact modeling and monitoring system, and output the associated metrics used to measure environmental footprints of an oil and gas production system. The environmental impact modeling and monitoring system may also measure in real time the actual environmental impact by leveraging sensors and gauges at various nodes of the oil and gas production system to internally calculate and output relevant sustainability metrics. In other words, the embodiments described herein automatically measure and quantify environmental impact in substantially real time based on field data collected by the sensors and gauges.

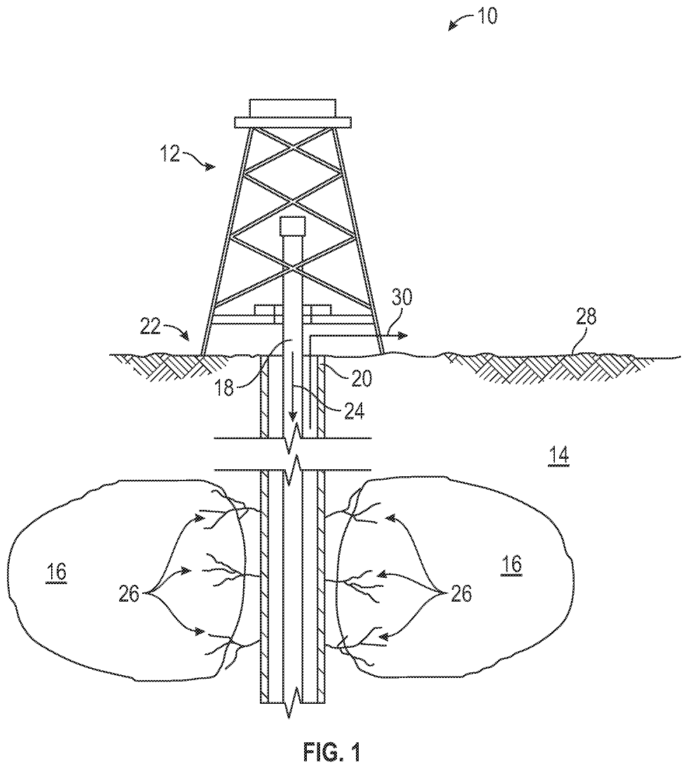

FIG. 1 illustrates a well site 10 having a drilling rig 12 positioned above a subterranean formation 14 that includes one or more oil and/or gas reservoirs 16. During operation, a derrick and a hoisting apparatus of the drilling rig 12 may raise and lower a drilling string 18 into and out of a wellbore 20 of a well 22 to drill the wellbore 20 into the subterranean formation 14, as well as to position downhole well tools within the wellbore 20 to facilitate completion and production operations of the well 22. For example, in certain operations, a hydraulic fracturing fluid (e.g., a fracturing slurry) may be introduced into the well 22 through the drilling string 18, as illustrated by arrow 24, which may be used to create fractures 26 in the subterranean formation 14 to facilitate production of oil and/or gas resources from the well 22. As described in greater detail herein, the produced water and the returned injected hydraulic fracturing fluid may be returned to the surface 28 of the well site 10 (e.g., through the annulus between the drilling string 18 and the wellbore 20), as illustrated by arrow 30. In certain circumstances, for every barrel of oil that is produced from a well 22, approximately three barrels of formation water (e.g., relatively high salt content water) are also produced.

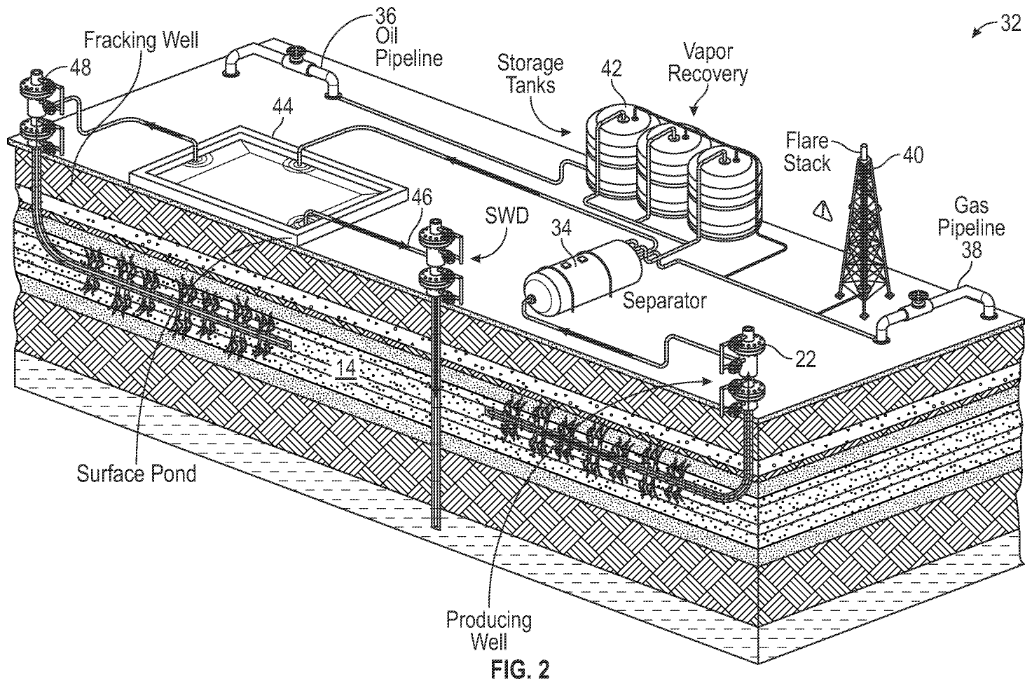

Oil and gas producers quite often contract for disposal and handling of the produced water with a midstream specialist firm focused on water handling and disposal (WHD). In many instances, the produced water is treated and injected in saltwater disposal (SWD) wells. FIG. 2 illustrates an example oil and gas production system 32. As illustrated in FIG. 2, oil and gas is produced along with water at one or more production wells 22. Then, each reservoir fluid (e.g., oil, gas, the produced water, the returned injected hydraulic fracturing fluid, and so forth) may be separated using one or more separators 34 with most of the produced oil and gas being directed into oil and gas pipelines 36, 38, respectively, and the remainder flared via a flare stack 40 and the produced water being directed to a temporary storage facility 42 for local (e.g., at the well site 10) treatment and subsequent storage in, for example, a surface pond 44. In certain embodiments, most of the produced water is re-injected into SWD wells 46 with only a small portion used for fracturing purposes via injection into a formation 14 by one or more fracturing wells 48.

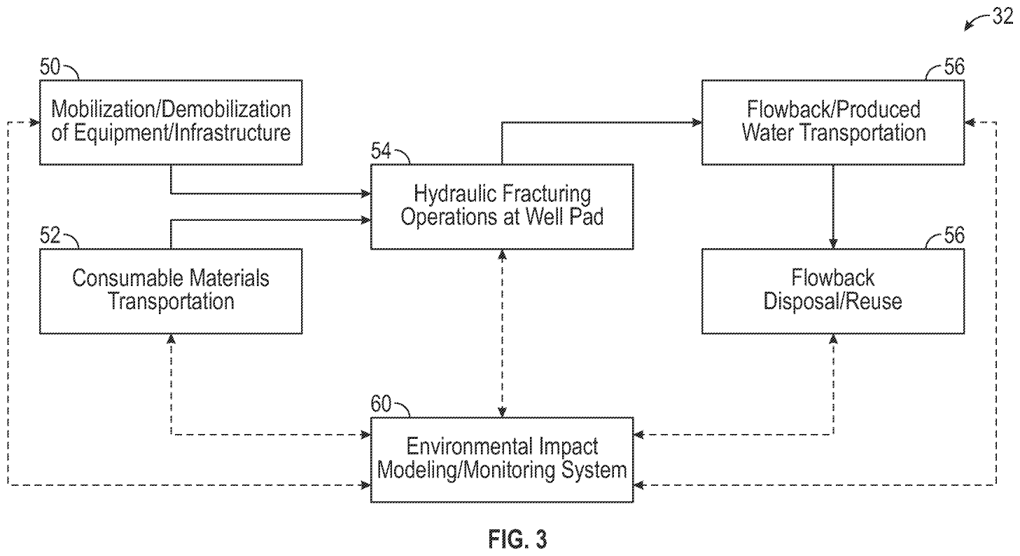

The oil and gas production system 32 illustrated in FIG. 2 may include a multitude of sub-systems, as described in greater detail herein. For example, FIG. 3 is a schematic diagram of various sub-systems of the oil and gas production system 32 of FIG. 2 (e.g., activities associated with delivering well completions of the oil and gas production system 32). As illustrated, in certain embodiments, the oil and gas production system 32 includes mobilization and demobilization 50 of equipment and infrastructure and consumable materials transportation 52 to establish the oil and gas production system 32 that, for example, enables hydraulic fracturing operations 54 at a well pad. In addition, in certain embodiments, the oil and gas production system 32 includes flowback (e.g., produced water) transportation 56 and flowback disposal and/or reuse 58. As described in greater detail herein, the oil and gas production system 32 also includes an environmental impact modeling and monitoring system 60 that enables continuous forecasting, real-time monitoring, and measurement of the environmental impact of well completion activities of the oil and gas production system 32. These activities include, but are not limited to, water management, sand management, fracturing operations, and all associated mobilization. As described in greater detail herein, in certain embodiments, the output of the environmental impact modeling and monitoring system 60 may be quantified parameters associated with sustainability metrics recognized across various industries.

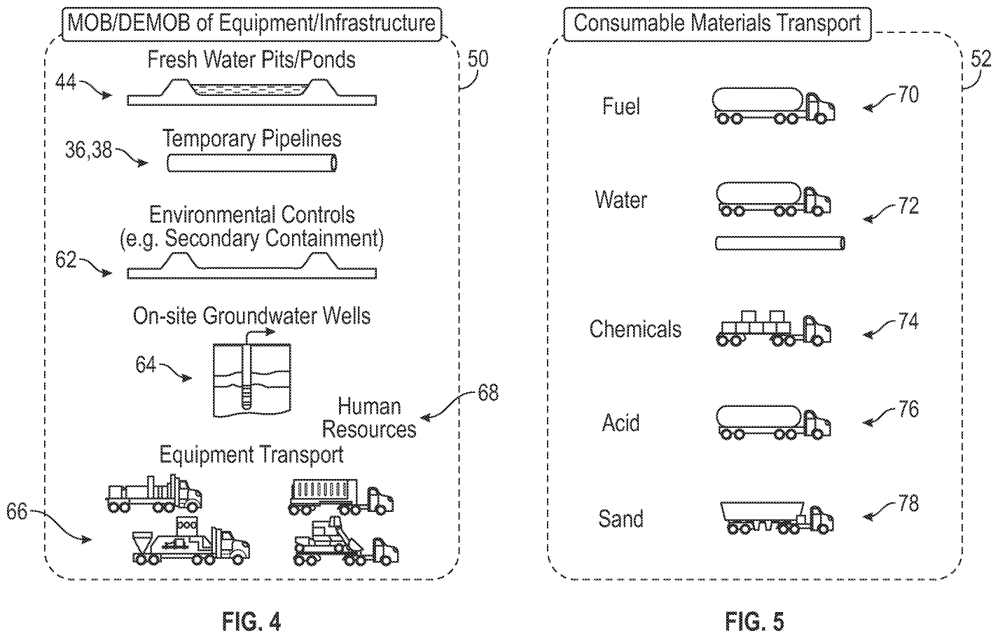

FIG. 4 illustrates various equipment and infrastructure that may be mobilized and demobilized as part of the mobilization and demobilization 50 illustrated in FIG. 3. For example, in certain embodiments, the mobilization and demobilization 50 may include creating freshwater pits/ponds 44 that may be used to provide freshwater to the oil and gas production system 32, as described in greater detail herein. In addition, in certain embodiments, the mobilization and demobilization 50 may include establishing other types of environmental controls (e.g., secondary containment mechanisms) 62 for the oil and gas production system 32, as described in greater detail herein. In addition, in certain embodiments, the mobilization and demobilization 50 may include creating on-site groundwater wells 64 that may be used to provide groundwater to the oil and gas production system 32, as described in greater detail herein. In addition, in certain embodiments, the mobilization and demobilization 50 may include installing temporary pipelines 36, 38 to facilitate the transfer of oil and gas (and, in certain embodiments, water) produced by the oil and gas production system 32, as described in greater detail herein. In addition, in certain embodiments, the mobilization and demobilization 50 may include transporting equipment (e.g., work trucks) 66 and human resources (e.g., workers) 68 to and from the oil and gas production system 32, as described in greater detail herein. In addition, in certain embodiments, the mobilization and demobilization 50 may include other types of mobilization and demobilization.

FIG. 5 illustrates various consumable materials that may be transported to the oil and gas production system 32 as part of the consumable materials transportation 52 illustrated in FIG. 3. For example, in certain embodiments, the consumable materials transportation 52 may include transporting fuel 70 (e.g., via trucks) to the oil and gas production system 32 to, for example, fuel various equipment of the oil and gas production system 32, as described in greater detail herein. In addition, in certain embodiments, the consumable materials transportation 52 may include transporting water 72 (e.g., via trucks and/or pipelines) to the oil and gas production system 32 to, for example, be used as a component for a fracturing slurry to be injected into one or more wells 22, 48 of the oil and gas production system 32, as described in greater detail herein. In addition, in certain embodiments, the consumable materials transportation 52 may include transporting chemicals 74 (e.g., via trucks) to the oil and gas production system 32 to, for example, be injected into one or more wells 22, 48 of the oil and gas production system 32, as described in greater detail herein. In addition, in certain embodiments, the consumable materials transportation 52 may include transporting acid 76 (e.g., via trucks) to the oil and gas production system 32 to, for example, be injected into one or more wells 22, 48 of the oil and gas production system 32, as described in greater detail herein. In addition, in certain embodiments, the consumable materials transportation 52 may include transporting sand 78 (e.g., via trucks) to the oil and gas production system 32 to, for example, be used as a component for a fracturing slurry to be injected into one or more wells 22, 48 of the oil and gas production system 32, as described in greater detail herein. In addition, in certain embodiments, the consumable materials transportation 52 may include transporting other types of consumable materials to the oil and gas production system 32.

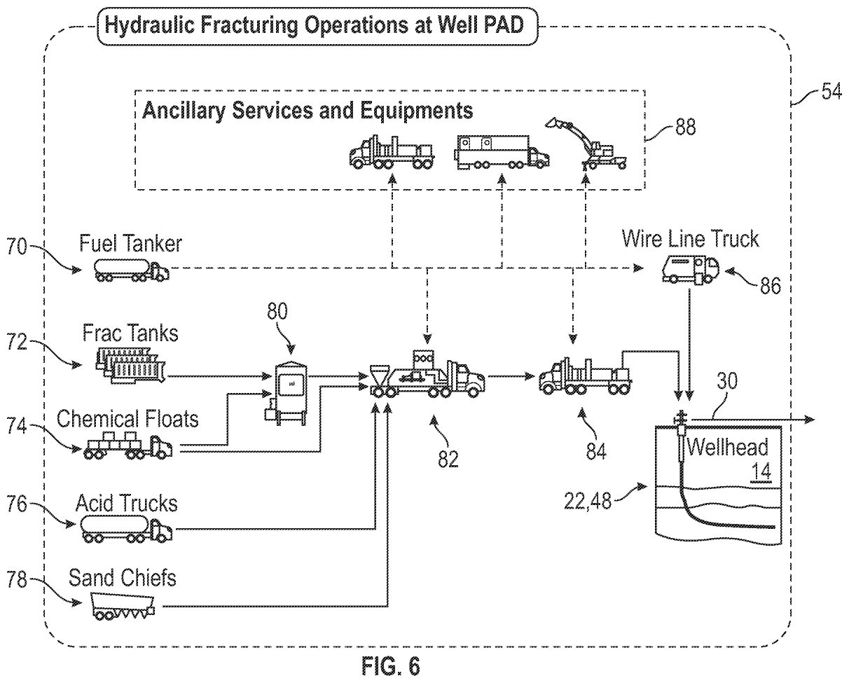

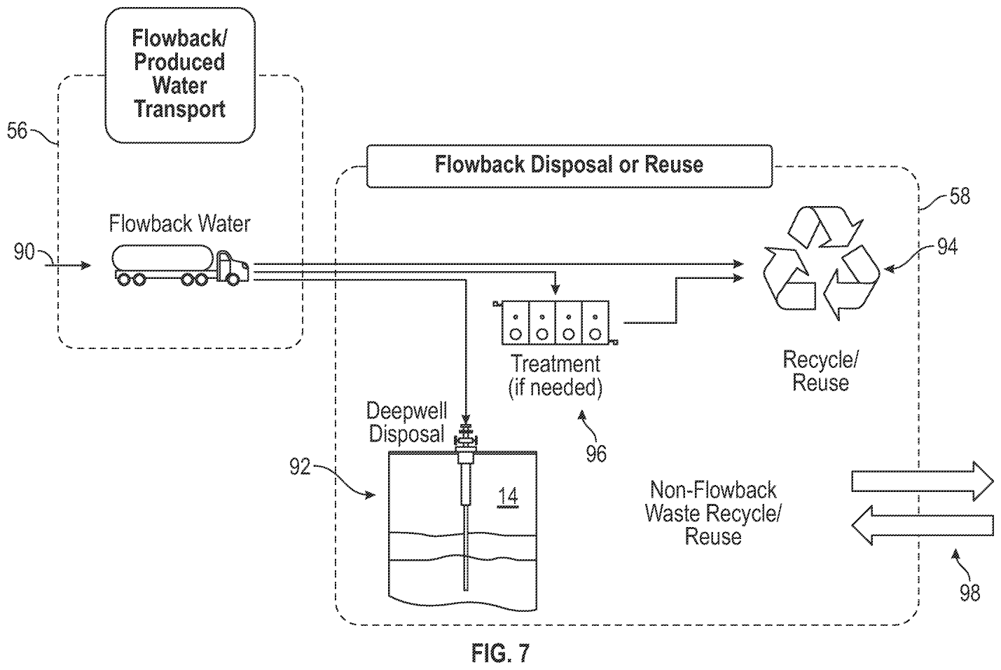

FIG. 6 illustrates example hydraulic fracturing operations 54 illustrated in FIG. 3. For example, in certain embodiments, the hydraulic fracturing operations 54 may include receiving the fuel 70 illustrated in FIG. 5 (e.g., via one or more fuel tankers), receiving the water 72 illustrated in FIG. 5 (e.g., into one or more fracturing tanks), receiving the chemicals 74 illustrated in FIG. 5 (e.g., via one or more chemical floats), receiving the acids 76 illustrated in FIG. 5 (e.g., via one or more acid trucks), and receiving the sand 78 illustrated in FIG. 5 (e.g., via one or more sand chiefs), as described in greater detail herein. In addition, in certain embodiments, the water 72 and the chemicals 74 may be directed into an additive system 80, and the mixture created by the additive system 80 may be directed into a fracturing slurry blender 82, along with additional chemicals 74, acids 76, and/or sand 78, and the fracturing slurry blender 82 may produce a fracturing slurry, which may then be pumped into one or more wells 22, 48 of the oil and gas production system 32, for example, by one or more high pressure pumps/manifold 84, as described in greater detail herein. In addition, in certain embodiments, a wireline truck 86 may be used as a logging unit to monitor downhole parameters of the one or more wells 22, 48 of the oil and gas production system 32, for example, by a downhole wireline tool controlled by the wireline truck 86, as described in greater detail herein. In addition, in certain embodiments, the fuel 70 may be delivered to the fracturing slurry blender 82, the high pressure pumps/manifold 84, the wireline truck 86, and other ancillary services and equipment 88 (e.g., cranes/booms, computer-aided treatment systems, seismic monitoring equipment, other pumping equipment, catering systems, maintenance equipment, and so forth) of the oil and gas production system 32, wherein the fuel 70 is used to power these components of the oil and gas production system 32, as described in greater detail herein. As illustrated in FIG. 6, the produced fluids 30 (e.g., including produced oil and gas, produced water, and recycled fracturing fluid) may be received from the one or more wells 22, 48 and handled as described in more detail with respect to FIG. 7, as described in greater detail herein.

For example, FIG. 7 illustrates the flowback/produced water transportation 56 and flowback disposal and/or reuse 58 illustrated in FIG. 3. In particular, the flowback/produced water portion 90 of the produced fluids 30 may be transported, for example, by trucks and/or pipelines for flowback disposal and/or reuse 58, as described in greater detail herein. For example, in certain embodiments, deepwater disposal wells 92 may be used to reinject at least some of the flowback/produced water portion 90 of the produced fluids 30 into one or more subterranean formations 14, as described in greater detail herein. In addition, in certain embodiments, at least some of the flowback/produced water portion 90 of the produced fluids 30 may be recycled/reused 94, as described in greater detail herein. In certain embodiments, the at least some of the flowback/produced water portion 90 of the produced fluids 30 may be treated, for example, by a water treatment system 96 before being recycled/reused 94, as described in greater detail herein. In addition, in certain embodiments, non-flowback waste 98 may also be recycled/reused.

Returning now to FIG. 3, as described in greater detail herein, the oil and gas production system 32 may include an environmental impact modeling and monitoring system 60 that enables continuous forecasting, real-time monitoring, and measurement of the environmental impact of well completion activities of the oil and gas production system 32. These activities include, but are not limited to, water management, sand management, fracturing operations, and all associated mobilization. As described in greater detail herein, in certain embodiments, the output of the environmental impact modeling and monitoring system 60 may be quantified parameters associated with sustainability metrics recognized across various industries.

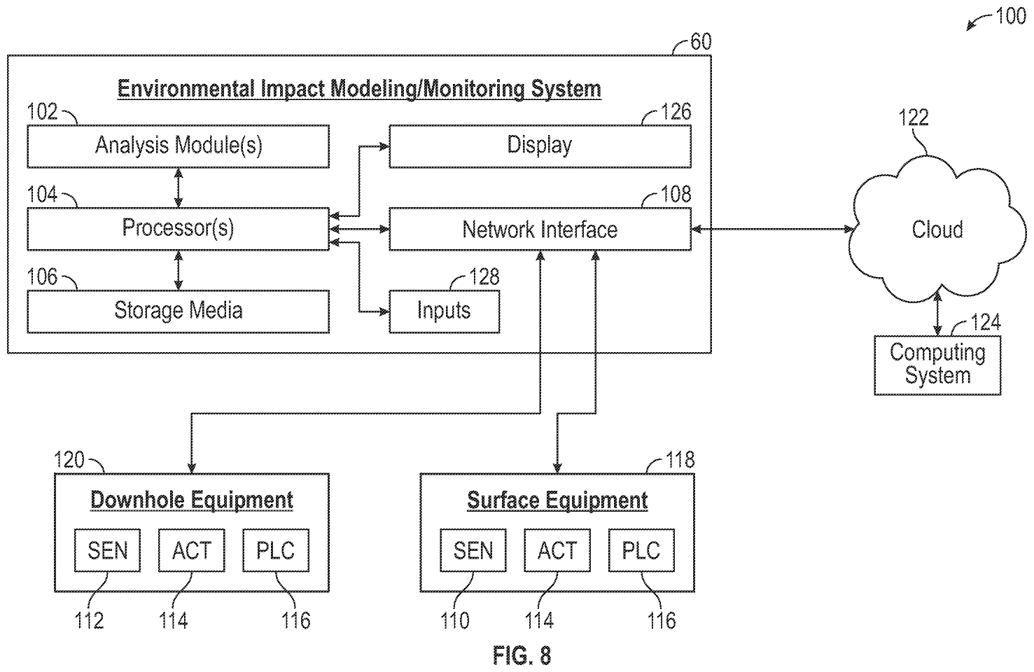

FIG. 8 illustrates a system 100 that includes an environmental impact modeling and monitoring system 60 to monitor and control the oil and gas production system 32 as described in greater detail herein. In certain embodiments, the environmental impact modeling and monitoring system 60 may include one or more analysis modules 102 (e.g., a program of processor executable instructions and associated data) that may be configured to perform various functions of the embodiments described herein. In certain embodiments, to perform these various functions, an analysis module 102 executes on one or more processors 104 of the environmental impact modeling and monitoring system 60, which may be connected to one or more storage media 106 of the environmental impact modeling and monitoring system 60. Indeed, in certain embodiments, the one or more analysis modules 102 may be stored in the one or more storage media 106.

In certain embodiments, the one or more processors 104 may include a microprocessor, a microcontroller, a processor module or subsystem, a programmable integrated circuit, a programmable gate array, a digital signal processor (DSP), or another control or computing device. In certain embodiments, the one or more storage media 106 may be implemented as one or more non-transitory computer-readable or machine-readable storage media. In certain embodiments, the one or more storage media 106 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; optical media such as compact disks (CDs) or digital video disks (DVDs); or other types of storage devices. Note that the processor-executable instructions and associated data of the analysis module(s) 102 may be provided on one computer-readable or machine-readable storage medium of the storage media 106 or, alternatively, may be provided on multiple computer-readable or machine-readable storage media distributed in a large system having possibly plural nodes. Such computer-readable or machine-readable storage medium or media are considered to be part of an article (or article of manufacture), which may refer to any manufactured single component or multiple components. In certain embodiments, the one or more storage media 106 may be located either in the machine running the machine-readable instructions, or may be located at a remote site from which machine-readable instructions may be downloaded over a network for execution.

In certain embodiments, the processor(s) 104 may be connected to a network interface 108 of the environmental impact modeling and monitoring system 60 to allow the environmental impact modeling and monitoring system 60 to communicate (e.g., either wirelessly or wired) with various surface sensors 110 (Internet of Things (IoT) sensors, gauges, and so forth) and/or downhole sensors 112 described herein, as well as communicate with actuators 114 and/or PLCs 116 of surface equipment 118 and/or of downhole equipment 120 for the purpose of monitoring and/or controlling operation of the oil and gas production system 32, as described in greater detail herein. In certain embodiments, the network interface 108 may also facilitate the environmental impact modeling and monitoring system 60 to communicate data to a cloud-based service 122 (or other wired and/or wireless communication network) to, for example, archive the data or to enable external computing systems 124 (e.g., remote servers, cloud-based computing systems, terminals, and so forth, in certain embodiments) to access the data and/or to remotely interact with the environmental impact modeling and monitoring system 60. For example, in certain embodiments, some or all of the analysis modules 102 described in greater detail herein may be executed via cloud and edge deployments. In addition, in certain embodiments, the external computing systems 124 may be used to enable users to remotely watch the data as it is collected and analyzed by the environmental impact modeling and monitoring system 60, as described in greater detail herein.

In certain embodiments, the environmental impact modeling and monitoring system 60 may include a display 126 configured to display a graphical user interface to present results on the analysis described herein. In addition, in certain embodiments, the graphical user interface may present other information to operators of the equipment 118, 120. For example, the graphical user interface may include a dashboard configured to present visual information to the operators. In certain embodiments, the dashboard may show live (e.g., real-time) data as well as the results of the analysis described herein. In addition, in certain embodiments, the environmental impact modeling and monitoring system 60 may include one or more input devices 128 configured to enable the operators to, for example, provide commands to the equipment 118, 120 described herein. In addition, in certain embodiments, the display 126 may include a touch screen interface configured to receive inputs from operators.

It should be appreciated that the system 100 illustrated in FIG. 8 is only exemplary, and that the system 100 may have more or fewer components than shown, may combine additional components not depicted in the embodiment of FIG. 8, and/or the system 100 may have a different configuration or arrangement of the components depicted in FIG. 8. In addition, the various components illustrated in FIG. 8 may be implemented in hardware, software, or a combination of both hardware and software, including one or more signal processing and/or application specific integrated circuits. Furthermore, the operations of the system 100 as described herein may be implemented by running one or more functional modules in an information processing apparatus such as application specific chips, such as application-specific integrated circuits (ASICs), field-programmable gate arrays (FPGAs), programmable logic devices (PLDs), systems on a chip (SOCs), or other appropriate devices. These modules, combinations of these modules, and/or their combination with hardware are all included within the scope of the embodiments described herein.

As described in greater detail herein, the environmental impact modeling and monitoring system 60 enables forecasting, real-time monitoring, and measuring the environmental impact of well completion activities of the oil and gas production system 32 described herein. As previously described, these activities include, but are not limited to, water management, sand management, fracturing operations, and all associated mobilization, among other activities. In certain embodiments, the outputs of the environmental impact modeling and monitoring system 60 may be quantified parameters associated with sustainability metrics recognized across various industries. In particular, the environmental impact modeling and monitoring system 60 enables operators to forecast the environmental impact based on job parameters inputted into the environmental impact modeling and monitoring system 60, and output the associated metrics used to measure environmental footprints of the oil and gas production system 32. The environmental impact modeling and monitoring system 60 may also measure in real time the actual environmental impact by leveraging sensors 110, 112 at various nodes of the oil and gas production system 32 to internally calculate and output relevant sustainability metrics. In other words, the environmental impact modeling and monitoring system 60 automatically measures and quantifies environmental impact in substantially real time based on field data collected by the sensors 110, 112.

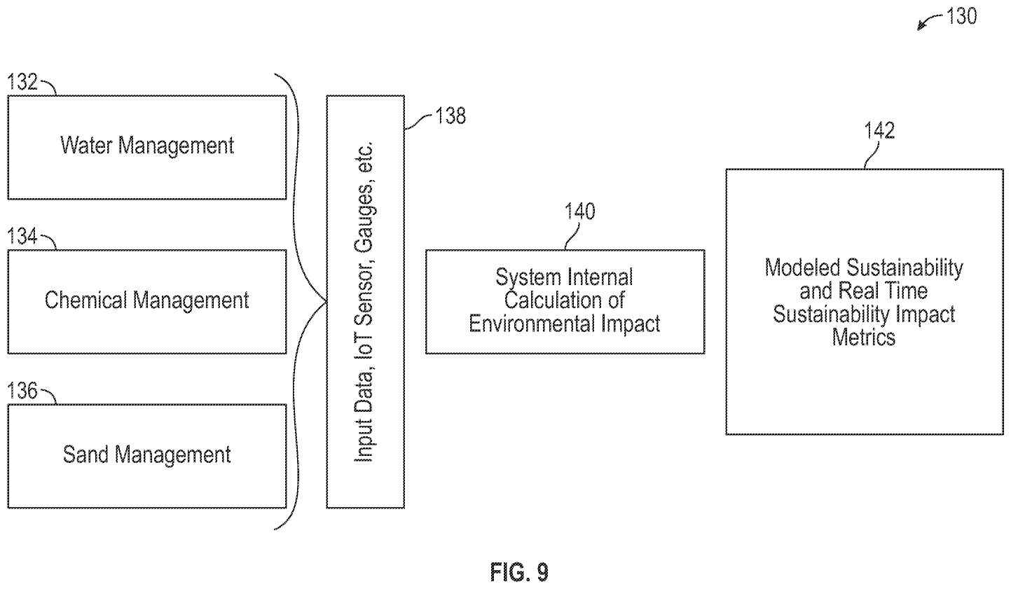

For example, FIG. 9 illustrates a process workflow 130 that may be performed by the environmental impact modeling and monitoring system 60 to model, monitor, and measure the environmental impact associated with well completion activities of the oil and gas production system 32 in substantially real time. As illustrated, in certain embodiments, the process workflow 130 may include water management 132, chemical management 134, and sand management 136, among other type of management that, for example, manage the mixing of water 72, chemicals 74, acid 76, and sand 78 (as illustrated in FIGS. 5 and 6) to produce a fracturing slurry that may be injected into one or more wells 22, 48, as described in greater detail herein.

In addition, in certain embodiments, during the water management 132, the chemical management 134, and the sand management 136, operational data may be collected by the sensors 110, 112 described herein in substantially real time, which may be used as input data 138 into the environmental impact modeling and monitoring system 60 to be used by the environmental impact modeling and monitoring system 60 to automatically calculate environmental impact parameters 140 of the oil and gas production system 32 in substantially real time during well completion activities performed by the oil and gas production system 32, as described in greater detail herein.

In certain embodiments, certain sensors 110, 112 associated with equipment (e.g., the surface and downhole equipment 118, 120 illustrated in FIG. 8) used to perform the water management 132 activities described herein may collect data relating to the water management 132 for the purpose of automatically determining (or updating) sustainability impact metrics 142 in substantially real time during well completion activities performed by the oil and gas production system 32 described herein using sustainability models, as described in greater detail herein. For example, referring to FIGS. 4-7, in certain embodiments, water quality, water levels, water flow rates, and other properties of water 72 in/from freshwater pits/ponds 44 may be detected by sensors 110 associated with the freshwater pits/ponds 44; water quality, water levels, water flow rates, and other properties of water 72 from groundwater wells 64 may be detected by sensors 110, 112 associated with the groundwater wells 64; water quality, water levels, water flow rates, and other properties of water 72 being injected into deepwater disposal wells 92 may be detected by sensors 110, 112 associated with the deepwater disposal wells 92; water quality, water levels, water flow rates, and other properties of water 72 (e.g., including flowback water) being transported through pipelines 36, 38 or by trucks may be detected by sensors 110 associated with the pipelines 36, 38 or trucks; water quality, water levels, water flow rates, and other properties of water 72 being processed by a water treatment system 96 may be detected by sensors 110 associated with the water treatment system 96; and so forth.

In addition, returning to FIG. 9, in certain embodiments, certain sensors 110 associated with equipment (e.g., the surface equipment 118 illustrated in FIG. 8) used to perform the chemical management 134 activities described herein may collect data relating to the chemical management 134 for the purpose of automatically determining (or updating) sustainability impact metrics 142 in substantially real time during well completion activities performed by the oil and gas production system 32 described herein. For example, referring to FIGS. 4-7, in certain embodiments, chemical compositions, chemical flow rates, and other properties of chemicals 74 being transported through pipelines 36, 38 or by trucks may be detected by sensors 110 associated with the pipelines 36, 38 or trucks; chemical compositions, chemical flow rates, and other properties of chemicals 74 being input into an additive system 80 may be detected by sensors 110 associated with the additive system 80; chemical compositions, chemical flow rates, and other properties of chemicals 74 being input into a fracturing slurry blender 82 may be detected by sensors 110 associated with the fracturing slurry blender 82; and so forth. In addition, in certain embodiments, acid compositions, acid flow rates, and other properties of acids 76 being transported through pipelines 36, 38 or by trucks may be detected by sensors 110 associated with the pipelines 36, 38 or trucks; acid compositions, acid flow rates, and other properties of acids 76 being input into an additive system 80 may be detected by sensors 110 associated with the additive system 80; acid compositions, acid flow rates, and other properties of acids 76 being input into a fracturing slurry blender 82 may be detected by sensors 110 associated with the fracturing slurry blender 82; and so forth.

In addition, returning to FIG. 9, in certain embodiments, certain sensors 110 associated with equipment (e.g., the surface equipment 118 illustrated in FIG. 8) used to perform the sand management 136 activities described herein may collect data relating to the sand management 136 for the purpose of automatically determining (or updating) sustainability impact metrics 142 in substantially real time during well completion activities performed by the oil and gas production system 32 described herein. For example, referring to FIGS. 4-7, in certain embodiments, sand compositions, sand volumes, and other properties of sand 78 being transported by trucks may be detected by sensors 110 associated with the trucks; acid compositions, sand compositions, sand volumes, and other properties of sand 78 being input into a fracturing slurry blender 82 may be detected by sensors 110 associated with the fracturing slurry blender 82; and so forth.

In addition, in certain embodiments, certain sensors 110, 112 associated with equipment (e.g., the surface and downhole equipment 118, 120 illustrated in FIG. 8) used to perform the hydraulic fracturing operations described herein may collect data relating to the hydraulic fracturing operations for the purpose of automatically determining (or updating) sustainability impact metrics 142 in substantially real time during well completion activities performed by the oil and gas production system 32 described herein. For example, in certain embodiments, slurry compositions, slurry volumes, slurry flow rates, slurry temperatures, slurry pressures, and other properties of fracturing slurry being pumped into one or more wells 22, 48 of the oil and gas production system 32 by high pressure pumps/manifold 84 may be detected by sensors 110, 112 associated with the high pressure pumps/manifold 84 and/or the one or more wells 22, 48.

In addition, in certain embodiments, certain sensors 110 associated with equipment (e.g., the surface equipment 118 illustrated in FIG. 8) used to perform the hydraulic fracturing operations described herein may collect data relating to fuel usage of the hydraulic fracturing operations for the purpose of automatically determining (or updating) sustainability impact metrics 142 in substantially real time during well completion activities performed by the oil and gas production system 32 described herein. For example, in certain embodiments, fuel compositions, fuel volumes, fuel flow rates, and other properties of fuel 70 being transported by transported through pipelines 36, 38 or by trucks may be detected by sensors 110 associated with the pipelines 36, 38 or trucks; fuel compositions, fuel volumes, fuel flow rates, and other properties of fuel 70 being consumed by the various surface equipment 118 described herein (e.g., additive system 80, fracturing slurry blenders 82, high pressure pumps/manifold 84, wireline trucks 86, ancillary services and equipment 88, among other surface equipment), and so forth.

In addition, in certain embodiments, certain sensors 110 associated with equipment (e.g., the surface equipment 118 illustrated in FIG. 8) may be configured to detect fugitive methane emissions of the equipment. In addition, in certain embodiments, certain sensors 110 associated with equipment (e.g., the surface equipment 118 illustrated in FIG. 8) may be configured to detect dust and venting of produced substances into the atmosphere from the equipment. In addition, in certain embodiments, certain sensors 110 associated with trucks used to transport the consumable materials described herein (e.g., fuel 70, water 72, chemicals 74, acids 76, sand 78, and so forth) may be configured to detect engine emissions of the trucks. In addition, in certain embodiments, certain sensors 110 associated with the trucks may be configured to detect location, movement, noise generated, and other operational parameters of the trucks for the purpose of enabling determination of the impact of the trucks on traffic, noise, and so forth.

Returning to FIG. 8, in certain embodiments, the environmental impact modeling and monitoring system 60 may receive data from any or all of the sensors 110, 112 described herein to automatically determine (or update) sustainability impact metrics 142 in substantially real time during well completion activities performed by the oil and gas production system 32 described herein. In certain embodiments, the sustainability impact metrics 142 automatically calculated (e.g., determined and/or updated) and outputted by the environmental impact modeling and monitoring system 60 may include, but are not limited to, total gas (e.g., methane and other greenhouse gas) emissions; total engine emissions; total power consumption (e.g., including electricity usage rates, natural gas usage rates, fuel usage rates, and so forth); water quality impact (e.g., the degradation of water quality during well completion activities); water usage rates; water disposal and/or recycling/reuse rates; chemical and/or acid usage rates; chemical and/or acid waste disposal and/or recycling/reuse rates; sand usage rates; dust, smoke, and other pollution rates; social impacts such as traffic and noise; and so forth. In certain embodiments, each of these sustainability impact metrics 142 may be automatically calculated (e.g., determined and/or updated) and outputted by the environmental impact modeling and monitoring system 60 as a ratio of oil and/or gas production rates for the oil and gas production system 32 (e.g., as per barrel of oil produced, as but one non-limiting example).

In certain embodiments, the analysis module(s) 102 utilized by the environmental impact modeling and monitoring system 60 to automatically determine (or update) the sustainability impact metrics 142 in substantially real time based on the data received from the sensors 110, 112 may include models of environmental impact parameters 140 that correlate the various types of data received from the sensors 110, 112 to automatically determine (or update) the impact of each of the types of data on the sustainability impact metrics 142. As but one non-limiting example, an increase in the amount of slurry used during hydraulic fracturing operations may have an indirect impact on the amount fugitive gas emissions, as observed based on historical data received from the sensors 110, 112. To that end, in certain embodiments, the analysis module(s) 102 may include machine learning algorithms that enable the analysis module(s) 102 to learn new correlations being various different types of data received from the sensors 110, 112 over time. In addition, in certain embodiments, such machine learning algorithms may be at least partially manually trained using expert knowledge entered by operators of the environmental impact modeling and monitoring system 60. In addition, in certain embodiments, the sustainability impact metrics 142 may be back-calculated by the machine learning algorithms based on historical data, statistical data, and/or manual inputs (e.g., equipment specifications, operational hours, and so forth), for example, in the event of missing inputs, faulty data, and so forth. Indeed, in certain embodiments, the machine learning algorithms may be configured to determine when data that is collected via the sensors 110, 112 is missing and/or faulty, and may then determine such historical data, statistical data, and/or manual inputs that should instead be used to calculate the sustainability impact metrics 142.

In certain embodiments, the environmental impact modeling and monitoring system 60 may be configured to automatically determine recommendations to improve certain environmental impacts of the oil and gas production system 32 based at least in part on the sustainability impact metrics 142 that are determined by the environmental impact modeling and monitoring system 60. In addition, in certain embodiments, the environmental impact modeling and monitoring system 60 may be configured to automatically control operating parameters of equipment 118, 120 of the oil and gas production system 32 based at least in part on the sustainability impact metrics 142 that are determined by the environmental impact modeling and monitoring system 60. For example, as but one non-limiting example, the environmental impact modeling and monitoring system 60 may be configured to automatically adjust the rate at which the fracturing slurry is pumped into a well 22, 48 in response to the environmental impact modeling and monitoring system 60 determining that fugitive gas emissions are elevated relative to normal levels. It will be appreciated that, in other embodiments, the operating parameters of the equipment 118, 120 of the oil and gas production system 32 may be manually controlled, for example, by operators of the oil and gas production system 32 based on recommendations that are generated by the environmental impact modeling and monitoring system 60, as described in greater detail herein.

It will be appreciated that the amount of data detected by the myriad sensors 110, 112 described herein may be massive, and that continuously transmitting data from the sensors 110, 112 to the environmental impact modeling and monitoring system 60 (e.g., via communication circuitry associated with the respective sensors 110, 112) may use a relatively large amount of network bandwidth, as well as requiring the environmental impact modeling and monitoring system 60 to perform a relatively large amount of processing to update the sustainability impact metrics 142 in substantially real time during well completion activities performed by the oil and gas production system 32 described herein. As such, in certain embodiments, the sensors 110, 112 (or equipment 118, 120 that includes, or is directly associated with, the respective sensors 110, 112) may be capable of determining when data should be transmitted to the environmental impact modeling and monitoring system 60 for analysis by, for example, determining a timing of such data transmission.

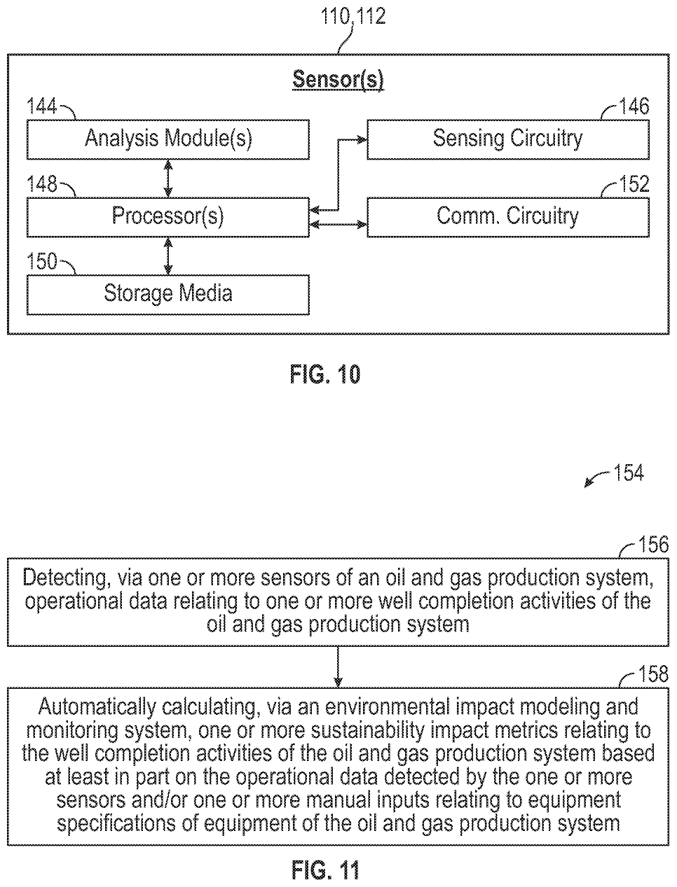

For example, as illustrated in FIG. 10, in certain embodiments, the sensors 110, 112 may include (or be associated with as part of equipment 118, 120 that includes, or is directly associated with, the respective sensors 110, 112) one or more analysis modules 144 (e.g., a program of processor executable instructions and associated data) that may be configured to perform various functions of the embodiments described herein including, but not limited to, minimizing data transmitted to the environmental impact modeling and monitoring system 60, for example, via local processing of the sensors 110, 112 (or of equipment 118, 120 that includes, or is directly associated with, the respective sensors 110, 112). For example, in certain embodiments, the one or more analysis modules 144 may be configured to determine, locally, whether data that has been recently detected by sensing circuitry 146 of the respective sensor 110, 112 has changed appreciably since a previous detection, and may only transmit the data to the environmental impact modeling and monitoring system 60 if, for example, the data has changed by more than a predetermined threshold amount. In addition, in certain embodiments, the one or more analysis modules 144 may be configured to transmit data to the environmental impact modeling and monitoring system 60 at data transmission rates that are determined based at least in part on a relative priority (e.g., importance) level of, for example, equipment 118, 120 to which the particular sensor 110, 112 is associated. For example, in certain embodiments, some sensors 110, 112 may be associated with communication circuitry to transmit data to the environmental impact modeling and monitoring system 60 continuously, whereas other sensors 110, 112 may only be associated with communication circuitry to transmit data to the environmental impact modeling and monitoring system 60 relatively sporadically (e.g., once every hour, once every day, and so forth).

In certain embodiments, to perform these various functions, an analysis module 144 executes on one or more processors 148 of the sensors 110, 112 (or of equipment 118, 120 that includes, or is directly associated with, the respective sensors 110, 112), which may be connected to one or more storage media 150 of the sensors 110, 112 (or of equipment 118, 120 that includes, or is directly associated with, the respective sensors 110, 112). Indeed, in certain embodiments, the one or more analysis modules 144 may be stored in the one or more storage media 150. In certain embodiments, the one or more processors 148 may include a microprocessor, a microcontroller, a processor module or subsystem, a programmable integrated circuit, a programmable gate array, a digital signal processor (DSP), or another control or computing device. In certain embodiments, the one or more storage media 150 may be implemented as one or more non-transitory computer-readable or machine-readable storage media. In certain embodiments, the one or more storage media 150 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; optical media such as compact disks (CDs) or digital video disks (DVDs); or other types of storage devices. Note that the processor-executable instructions and associated data of the analysis module(s) 144 may be provided on one computer-readable or machine-readable storage medium of the storage media 150 or, alternatively, may be provided on multiple computer-readable or machine-readable storage media distributed in a large system having possibly plural nodes. Such computer-readable or machine-readable storage medium or media are considered to be part of an article (or article of manufacture), which may refer to any manufactured single component or multiple components. In certain embodiments, the one or more storage media 150 may be located either in the machine running the machine-readable instructions, or may be located at a remote site from which machine-readable instructions may be downloaded over a network for execution.

In certain embodiments, the processor(s) 148 may be connected to communication circuitry 152 of the sensors 110, 112 (or of equipment 118, 120 that includes, or is directly associated with, the respective sensors 110, 112) to allow the sensors 110, 112 to communicate (e.g., either wirelessly or wired) with the environmental impact modeling and monitoring system 60 for the purpose of enabling the environmental impact modeling and monitoring system 60 to monitor and/or control operation of the oil and gas production system 32, as described in greater detail herein. It will be appreciated that, due at least in part to the various different communication protocols that may be employed by the communication circuitry 152 used to collect data for a particular oil and gas production system 32, in certain embodiments, both the sensors 110, 112 (or equipment 118, 120 that includes, or is directly associated with, the respective sensors 110, 112) and the environmental impact modeling and monitoring system 60 may be configured to convert data transmitted and/or received from the other from one communication format to another communication format to facilitate communication of the data between them. Indeed, in certain embodiments, the conversion of the data into suitable communication formats may also facilitate further reduction in network bandwidth usage insofar as one or both of the communication formats may enable data encryption/decryption and/or data compression to facilitate the communication of the data via the different communication protocols.

As such, the embodiments described herein enable continuous monitoring of well completion activities of an oil and gas production system 32 via sensors 110, 112 for the purpose of enabling real-time provision of sustainability impact metrics 142 relating to the well completion activities in a manner that was heretofore not possible. In particular, the embodiments described herein include an environmental impact modeling and monitoring system 60 that is configured to receive data relating to the well completion activities from the sensors 110, 112 as efficiently as possible (e.g., by minimizing the frequency of data transmission to an extent) while still providing substantially real-time (and up-to-date) sustainability impact metrics 142 during performance of the well completion activities (e.g., as updated data becomes available), as described in greater detail herein.

FIG. 11 is a flow diagram of a method 154 of use of the environmental impact modeling and monitoring system 60 described herein. As illustrated, in certain embodiments, the method 154 includes detecting, via one or more sensors 110, 112 of an oil and gas production system 32, operational data relating to one or more well completion activities of the oil and gas production system 32 (block 156). In addition, in certain embodiments, the method 154 includes automatically calculating, via an environmental impact modeling and monitoring system 60, one or more sustainability impact metrics 142 relating to the well completion activities of the oil and gas production system 32 based at least in part on the operational data detected by the one or more sensors 110, 112 and/or one or more manual inputs relating to equipment specifications of equipment 118, 120 of the of the oil and gas production system 32 (block 158). In addition, in certain embodiments, the method 154 includes automatically calculating, via the environmental impact modeling and monitoring system 60, the one or more sustainability impact metrics 142 relating to the well completion activities of the oil and gas production system 32 based at least in part on historical data, statistical data, and/or manual inputs (e.g., equipment specifications, operational hours, and so forth), for example, in the event of missing inputs, faulty data, and so forth. Indeed, in certain embodiments, the environmental impact modeling and monitoring system 60 may be configured to determine when data that is collected via the sensors 110, 112 is missing and/or faulty, and may then determine such historical data, statistical data, and/or manual inputs that should instead be used to calculate the sustainability impact metrics 142.

In addition, in certain embodiments, the method 154 includes automatically calculating, via the environmental impact modeling and monitoring system 60, the one or more sustainability impact metrics 142 relating to the well completion activities of the oil and gas production system 32 in substantially real time during performance of the well completion activities. In addition, in certain embodiments, the method 154 includes automatically calculating, via the environmental impact modeling and monitoring system 60, the one or more sustainability impact metrics 142 relating to the well completion activities of the oil and gas production system 32 based at least in part on machine learning algorithms that are trained based on historical data. In addition, in certain embodiments, the method 154 includes automatically determining, via the environmental impact modeling and monitoring system 60, one or more recommendations to improve certain environmental impacts of the oil and gas production system 32 based at least in part on the sustainability impact metrics 142 that are determined by the environmental impact modeling and monitoring system 60. In addition, in certain embodiments, the method 154 includes automatically adjusting, via the environmental impact modeling and monitoring system 60, one or more operating parameters of equipment 118, 120 of the oil and gas production system 32 based at least in part on the one or more sustainability impact metrics 142. It will be appreciated that, in other embodiments, the one or more operating parameters of the equipment 118, 120 of the oil and gas production system 32 may be manually controlled, for example, by operators of the oil and gas production system 32 based at least in part on recommendations that are generated by the environmental impact modeling and monitoring system 60, as described in greater detail herein.

In addition, in certain embodiments, the method 154 includes receiving, via the environmental impact modeling and monitoring system 60, the operational data from communication circuitry 152 associated with the one or more sensors 110, 112 using at least two different communication protocols. In addition, in certain embodiments, the method 154 includes determining, via processing circuitry 148 the one or more sensors 110, 112, a timing of transmission of the operational data to the environmental impact modeling and monitoring system 60.

In certain embodiments, the one or more well completion activities comprise water management activities 132. In addition, in certain embodiments, the one or more well completion activities comprise chemical management activities 134. In addition, in certain embodiments, the one or more well completion activities comprise sand management activities 136.

In certain embodiments, the one or more sensors 110, 112 are associated with one or more pipelines 36, 38 or trucks transporting consumable materials to the oil and gas production system 32. In addition, in certain embodiments, the one or more sensors 110 are associated with surface equipment 118 performing at least a portion of the one or more well completion activities of the oil and gas production system 32. In addition, in certain embodiments, the one or more sensors 112 are associated with downhole equipment 120 performing at least a portion of the one or more well completion activities of the oil and gas production system 32.

In certain embodiments of the present disclosure, a method includes detecting, via one or more sensors of an oil and gas production system, operational data relating to one or more well completion activities of the oil and gas production system. The method also includes automatically calculating, via an environmental impact modeling and monitoring system, one or more sustainability impact metrics relating to the well completion activities of the oil and gas production system based at least in part on the operational data detected by the one or more sensors and/or one or more manual inputs relating to equipment specifications of equipment of the oil and gas production system.

In some embodiments, the method also includes automatically calculating, via the environmental impact modeling and monitoring system, the one or more sustainability impact metrics relating to the well completion activities of the oil and gas production system in substantially real time during performance of the well completion activities. In some embodiments, the method also includes automatically calculating, via the environmental impact modeling and monitoring system, the one or more sustainability impact metrics relating to the well completion activities of the oil and gas production system based at least in part on machine learning algorithms that are trained on historical data.

In some embodiments, the methods also includes determining, via the environmental impact modeling and monitoring system, one or more recommendations to improve an environmental impact relating to the well completion activities of the oil and gas production system based at least in part on the one or more sustainability impact metrics. In some embodiments, the method also includes adjusting, via the environmental impact modeling and monitoring system, one or more operating parameters of the equipment of the oil and gas production system based at least in part on the one or more sustainability impact metrics. In some embodiments, the method also includes receiving, via the environmental impact modeling and monitoring system, the operational data from communication circuitry associated with the one or more sensors using at least two different communication protocols. In some embodiments the method also includes determining, via processing circuitry associated with the one or more sensors, a timing of transmission of the operational data to the environmental impact modeling and monitoring system.

In some embodiments, the one or more well completion activities include water management activities. In some embodiments, the one or more well completion activities include chemical management activities. In some embodiments, the one or more well completion activities include sand management activities.

In some embodiments, the one or more sensors are associated with one or more pipelines or trucks transporting consumable materials to the oil and gas production system. In some embodiments, the one or more sensors are associated with surface equipment performing at least a portion of the one or more well completion activities of the oil and gas production system. In some embodiments, the one or more sensors are associated with downhole equipment performing at least a portion of the one or more well completion activities of the oil and gas production system.

In certain embodiments of the present disclosure, a system includes one or more sensors of an oil and gas production system and an environmental impact modeling and monitoring system. The sensors are configured to detect operational data relating to one or more well completion activities of the oil and gas production system. The environmental impact modeling and monitoring system is configured to automatically calculate one or more sustainability impact metrics relating to the well completion activities of the oil and gas production system based at least in part on the operational data detected by the one or more sensors and/or one or more manual inputs relating to equipment specifications of equipment of the oil and gas production system.

In some embodiments, the environmental impact modeling and monitoring system is configured to automatically calculate the one or more sustainability impact metrics relating to the well completion activities of the oil and gas production system in substantially real time during performance of the well completion activities. In some embodiments, the environmental impact modeling and monitoring system is configured to automatically calculate the one or more sustainability impact metrics relating to the well completion activities of the oil and gas production system based at least in part on machine learning algorithms that are trained on historical data.

In some embodiments, the environmental impact modeling and monitoring system is configured to automatically determine one or more recommendations to improve an environment impact relating to the well completion activities of the oil and gas production system based at least in part on the one or more sustainability impact metrics. In some embodiments, the environmental impact modeling and monitoring system is configured to adjust one or more operating parameters of the equipment of the oil and gas production system based at least in part on the one or more sustainability impact metrics. In some embodiments, the environmental impact modeling and monitoring system is configured to receive the operational data from communication circuitry associated with the one or more sensors using at least two different communication protocols. In some embodiments, processing circuitry associated with the one or more sensors are configured to determine at timing of transmission of the operational data to the environmental impact modeling and monitoring system.

The specific embodiments described above have been illustrated by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

1. A method, comprising:
detecting, via one or more sensors of an oil and gas production system, operational data relating to one or more well completion activities of the oil and gas production system; and
automatically calculating, via an environmental impact modeling and monitoring system, one or more sustainability impact metrics relating to the well completion activities of the oil and gas production system based at least in part on the operational data detected by the one or more sensors and/or one or more manual inputs relating to equipment specifications of equipment of the oil and gas production system.

2. The method of claim 1, comprising automatically calculating, via the environmental impact modeling and monitoring system, the one or more sustainability impact metrics relating to the well completion activities of the oil and gas production system in substantially real time during performance of the well completion activities.

3. The method of claim 1, comprising automatically calculating, via the environmental impact modeling and monitoring system, the one or more sustainability impact metrics relating to the well completion activities of the oil and gas production system based at least in part on machine learning algorithms that are trained based on historical data.

4. The method of claim 1, comprising automatically determining, via the environmental impact modeling and monitoring system, one or more recommendations to improve an environment impact relating to the well completion activities of the oil and gas production system based at least in part on the one or more sustainability impact metrics.

5. The method of claim 1, comprising adjusting, via the environmental impact modeling and monitoring system, one or more operating parameters of the equipment of the oil and gas production system based at least in part on the one or more sustainability impact metrics.

6. The method of claim 1, comprising receiving, via the environmental impact modeling and monitoring system, the operational data from communication circuitry associated with the one or more sensors using at least two different communication protocols.

7. The method of claim 6, comprising determining, via processing circuitry associated with the one or more sensors, a timing of transmission of the operational data to the environmental impact modeling and monitoring system.

8. The method of claim 1, wherein the one or more well completion activities comprise water management activities.

9. The method of claim 1, wherein the one or more well completion activities comprise chemical management activities.

10. The method of claim 1, wherein the one or more well completion activities comprise sand management activities.

11. The method of claim 1, wherein the one or more sensors are associated with one or more pipelines or trucks transporting consumable materials to the oil and gas production system.

12. The method of claim 1, wherein the one or more sensors are associated with surface equipment performing at least a portion of the one or more well completion activities of the oil and gas production system.

13. The method of claim 1, wherein the one or more sensors are associated with downhole equipment performing at least a portion of the one or more well completion activities of the oil and gas production system.

14. A system, comprising:
one or more sensors of an oil and gas production system, wherein the one or more sensors are configured to detect operational data relating to one or more well completion activities of the oil and gas production system; and
an environmental impact modeling and monitoring system configured to automatically calculate one or more sustainability impact metrics relating to the well completion activities of the oil and gas production system based at least in part on the operational data detected by the one or more sensors and/or one or more manual inputs relating to equipment specifications of equipment of the of the oil and gas production system.

15. The system of claim 14, wherein the environmental impact modeling and monitoring system is configured to automatically calculate the one or more sustainability impact metrics relating to the well completion activities of the oil and gas production system in substantially real time during performance of the well completion activities.

16. The system of claim 14, wherein the environmental impact modeling and monitoring system is configured to automatically calculate the one or more sustainability impact metrics relating to the well completion activities of the oil and gas production system based at least in part on machine learning algorithms that are trained based on historical data.

17. The system of claim 14, wherein the environmental impact modeling and monitoring system is configured to automatically determine one or more recommendations to improve an environment impact relating to the well completion activities of the oil and gas production system based at least in part on the one or more sustainability impact metrics.

18. The system of claim 14, wherein the environmental impact modeling and monitoring system is configured to adjust one or more operating parameters of the equipment of the oil and gas production system based at least in part on the one or more sustainability impact metrics.

19. The system of claim 14, wherein the environmental impact modeling and monitoring system is configured to receive the operational data from communication circuitry associated with the one or more sensors using at least two different communication protocols.

20. The system of claim 14, wherein processing circuitry associated with the one or more sensors are configured to determine a timing of transmission of the operational data to the environmental impact modeling and monitoring system.
